(19) United States
(12) Patent Application Publication
(10) Pub. No.: US 2023/0317909 A1
(43) Pub. Date: Oct. 5, 2023

(54) LIGHT-EMITTING MODULE AND METHOD FOR MANUFACTURING LIGHT-EMITTING MODULE

(71) Applicant: NICHIA CORPORATION, Anan-shi (JP)

(72) Inventor: Katsuyoshi KADAN, Katsuura-gun (JP)

(73) Assignee: NICHIA CORPORATION, Anan-shi (JP)

(21) Appl. No.: 18/190,923

(22) Filed: Mar. 27, 2023

(30) Foreign Application Priority Data
Mar. 30, 2022 (JP) 2022-056735

(51) Int. Cl. H01L 33/62; H01L 25/075; H01L 33/60

(52) U.S. Cl. CPC H01L 33/62; H01L 25/0753; H01L 33/60; H01L 2933/0066; H01L 2933/0058

(57) ABSTRACT

A light-emitting module includes a substrate including a support member having a first surface, and a wiring layer arranged on the first surface. The light-emitting modules further include a light-shielding member arranged on the first surface and having a plurality of holes in plan view, a plurality of light-emitting elements respectively arranged inside the plurality of holes on the first surface and electrically connected to the wiring layer, a first light-transmissive member having a plurality of convex bodies respectively arranged on light extraction surfaces of the plurality of light-emitting elements inside the plurality of holes, and a plurality of gaps respectively arranged in contact with the wiring layer between the plurality of light-emitting elements and inner peripheral surfaces of the plurality of holes.

### CROSS-REFERENCE TO RELATED APPLICATIONS

The present application claims priority under 35 U.S.C. § 119 to Japanese Patent Application No. 2022-056735, filed Mar. 30, 2022, the contents of which are hereby incorporated by reference in their entirety.

### BACKGROUND

### 1. Technical Field

Embodiments relate to a light-emitting module and a method for manufacturing the light-emitting module.

### 2. Description of Related Art

Light-emitting modules in which a large number of light-emitting elements are two-dimensionally arranged are widely used as backlights of liquid crystal displays and various planar light sources such as displays.

The light-emitting module can be downsized and thinned by using an ultra-small bare chip for a light-emitting element serving as a light source. The downsized and thinned light-emitting module has a great advantage including further improvement in light extraction efficiency that makes it possible to expand the mounting application and further improvement in the efficiency. (See, e.g., Patent Document 1—Japanese Patent Publication No. 2016-525288.)

### SUMMARY

A light-emitting module is provided herein with improved light extraction efficiency, as is a method for manufacturing the light-emitting module.

A light-emitting module according to an embodiment includes: a substrate including a support member having a first surface, and a wiring layer arranged on the first surface; a light-shielding member arranged on the first surface and having a plurality of holes in plan view; a plurality of light-emitting elements respectively arranged inside the plurality of holes on the first surface and electrically connected to the wiring layer; a first light-transmissive member having a plurality of convex bodies respectively arranged on light extraction surfaces of the plurality of light-emitting elements inside the plurality of holes; and a plurality of gaps respectively arranged in contact with the wiring layer between the plurality of light-emitting elements and inner peripheral surfaces of the plurality of holes.

A light-emitting module according to an embodiment includes: a substrate including a support member having a first surface and a wiring layer arranged on the first surface; a light-shielding member arranged on the first surface and having a hole in plan view; a light-emitting element arranged inside the hole on the first surface and electrically connected to the wiring layer; a first light-transmissive member having a convex body arranged on a light extraction surface of the light-emitting element inside the hole; and a gap arranged in contact with the wiring layer between the light-emitting element and an inner peripheral surface of the hole.

A method for manufacturing a light-emitting module according to an embodiment includes preparing a first intermediate member including a substrate including a support member having a first surface and a wiring layer arranged on the first surface, a plurality of light-emitting elements arranged on the first surface apart from one another and connected to the wiring layer, and a light-shielding member having a plurality of holes and having the plurality of light-emitting elements respectively arranged inside the plurality of holes; and arranging a plurality of convex bodies having transmissivity on upper surfaces of the plurality of light-emitting elements via the plurality of holes. The arranging of the plurality of convex bodies on the upper surfaces of the plurality of light-emitting elements includes respectively arranging a plurality of gaps in contact with the wiring layer between the plurality of light-emitting elements and inner peripheral surfaces of the plurality of holes.

Accordingly, a light-emitting module with improved light extraction efficiency and a method for manufacturing the light-emitting module can be provided.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a schematic top view illustrating a light-emitting module according to a first embodiment.

FIG. 2 is an enlarged view of the part II in FIG. 1.

FIG. 3 is a cross-sectional view taken along line of FIG. 2, and is a schematic cross-sectional view illustrating the light-emitting module according to the first embodiment.

FIG. 4 is a schematic top view illustrating a light-emitting module according to a modified example of the first embodiment.

FIG. 5A is a schematic cross-sectional view illustrating a method for manufacturing the light-emitting module according to the first embodiment.

FIG. 5B is a schematic cross-sectional view illustrating the method for manufacturing the light-emitting module according to the first embodiment.

FIG. 6A is a schematic cross-sectional view illustrating the method for manufacturing the light-emitting module according to the first embodiment.

FIG. 6B is a schematic cross-sectional view illustrating the method for manufacturing the light-emitting module according to the first embodiment.

FIG. 7A is a schematic cross-sectional view illustrating the method for manufacturing the light-emitting module according to the first embodiment.

FIG. 7B is a schematic cross-sectional view illustrating the method for manufacturing the light-emitting module according to the first embodiment.

FIG. 8A is a schematic cross-sectional view illustrating the method for manufacturing the light-emitting module according to the first embodiment.

FIG. 8B is a schematic cross-sectional view illustrating the method for manufacturing the light-emitting module according to the first embodiment.

FIG. 9A is a schematic cross-sectional view illustrating a modified example of the method for manufacturing the light-emitting module according to the first embodiment.

FIG. 9B is a schematic cross-sectional view illustrating a modified example of the method for manufacturing the light-emitting module according to the first embodiment.

FIG. 10 is a schematic cross-sectional view illustrating a modified example of the method for manufacturing the light-emitting module according to the first embodiment.

FIG. 11 is a schematic cross-sectional view illustrating a light-emitting module according to a second embodiment.

FIG. 12A is a schematic cross-sectional view illustrating a method for manufacturing the light-emitting module according to the second embodiment.

FIG. 12B is a schematic cross-sectional view illustrating the method for manufacturing the light-emitting module according to the second embodiment.

FIG. 13A is a schematic cross-sectional view illustrating the method for manufacturing the light-emitting module according to the second embodiment.

FIG. 13B is a schematic cross-sectional view illustrating the method for manufacturing the light-emitting module according to the second embodiment.

FIG. 14 is a schematic cross-sectional view illustrating a light-emitting module according to a third embodiment.

FIG. 15 is a schematic cross-sectional view illustrating a light-emitting module according to a fourth embodiment.

FIG. 16A is a schematic cross-sectional view illustrating a light-emitting module according to Modified Example 1 of the fourth embodiment.

FIG. 16B is a schematic cross-sectional view illustrating a light-emitting module according to Modified Example 2 of the fourth embodiment.

FIG. 16C is a schematic cross-sectional view illustrating a light-emitting module according to Modified Example 3 of the fourth embodiment.

FIG. 17 is a schematic cross-sectional view illustrating a light-emitting module according to a fifth embodiment.

### DESCRIPTION OF EMBODIMENTS

Embodiments of the present invention will be described below with reference to the drawings.

Note that the drawings are schematic or conceptual, and the relationship between the thickness and the width of each portion, the size ratio between parts, and the like are not necessarily the same as the actual values. Further, the dimensions and the proportions may be different depending on the drawings, even when the same portion is illustrated.

Note that, in the present specification and in each drawing, elements same as or similar to those described above in relation to the drawings already described are denoted by the same characters, and detailed descriptions are omitted as appropriate.

### First Embodiment

Configuration of Light-Emitting Module 100

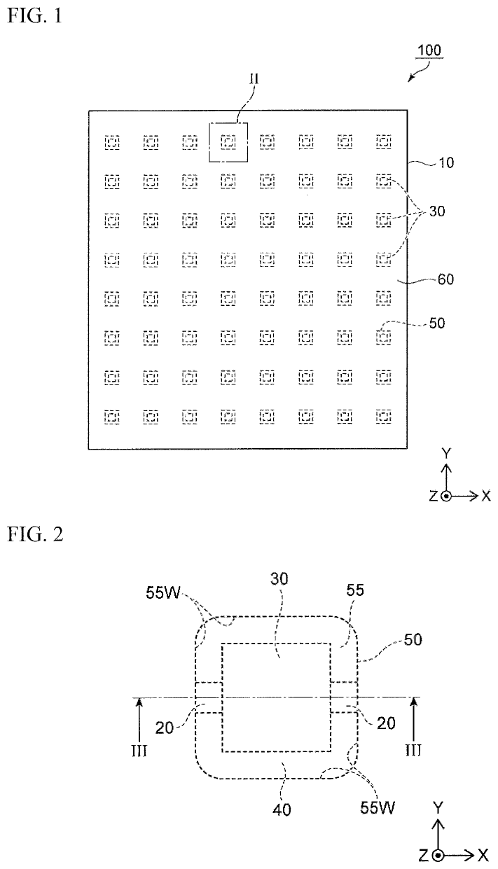

FIG. 1 is a schematic top view illustrating a light-emitting module according to a first embodiment.

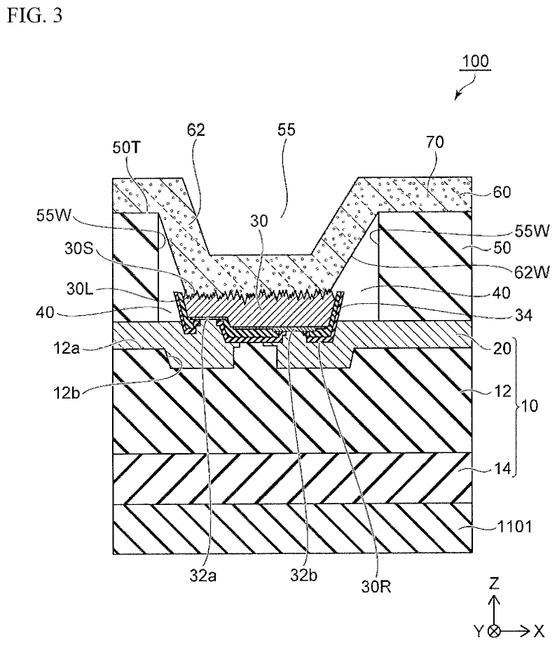

FIG. 2 is an enlarged view of the part II in FIG. 1.

FIG. 3 is a cross-sectional view taken along line of FIG. 2, and is a schematic cross-sectional view illustrating the light-emitting module according to the first embodiment.

As illustrated in FIGS. 1 to 3, a light-emitting module 100 according to the present embodiment includes a substrate 10, a plurality of light-emitting elements 30, a plurality of gaps 40, a light-shielding member 50, and a first light-transmissive member 60. The substrate 10 includes a support member 12 and a wiring layer 20. The support member 12 has a first surface 12a. The wiring layer 20 is arranged on the first surface 12a. The plurality of light-emitting elements 30 are arranged on the first surface 12a.

In the description of all embodiments and the modified examples thereof, three-dimensional XYZ coordinates can be used. The XY plane is a plane substantially parallel to the first surface 12a. The direction of the X axis is a direction along the row direction of the plurality of light-emitting elements 30 arranged in a matrix. The direction of the Y axis is a direction along the column direction of the plurality of light-emitting elements 30 arranged in a matrix. The Y axis is orthogonal to the X axis. The Z axis is orthogonal to the XY plane. It is assumed that an orientation from a surface located on the opposite side of the support member 12 from the first surface 12a toward the first surface 12a is a positive direction.

The positive direction of the Z axis is sometimes referred to as “up”, “upper”, or “upward” and the negative direction of the Z axis is sometimes referred to as “down”, “lower”, “downward”. However, the direction along the Z axis is not necessarily the direction in which gravity is applied. These are intended to facilitate understanding of the description, and are not limited to actual “up”, “upper”, “upward”, “down”, “lower”, or “downward”. The length in the Z axis direction is sometimes referred to as thickness.

As illustrated in FIGS. 1 and 2, in the light-emitting module 100, the plurality of light-emitting elements 30 are arranged in a matrix of eight rows by eight columns on the substrate 10 that is substantially square in XY plane view. The number of rows and the number of columns in which the plurality of light-emitting elements 30 are arranged are not limited to this, and for example, the number of rows and the number of columns can be set as necessary according to the application. The arrangement of the plurality of light-emitting elements 30 is not limited to the matrix arrangement as illustrated in FIG. 1, and can be any appropriate arrangement such as a staggered arrangement or a hexagonal close-packed arrangement.

In the arrangement of the plurality of light-emitting elements 30 in the example of FIG. 1, the spacing between the adjacent light-emitting elements 30 is the same for all the light-emitting elements 30. The spacing between the adjacent light-emitting elements 30 is not limited to this and can be different depending on the position of the light-emitting element 30 in the light-emitting module 100. For example, in the corner of the light-emitting module 100, the number of adjacent light-emitting elements is reduced, and interference due to light between the light-emitting elements is reduced, and thus the brightness is lower than that in the center of the light-emitting module 100. Thus, the spacing between the light-emitting elements 30 can be narrower in the corner of the light-emitting module 100 than the spacing between the light-emitting elements 30 in the center of the light-emitting module 100, to increase the brightness. The shape of the substrate 10 is not limited to a square, and can be a rectangle or any polygon such as a trapezoid or a rhombus depending on the number of the light-emitting elements 30 to be arranged and the aspect of arrangement.

In the light-emitting module 100, the light-shielding member 50 has a plurality of holes 55 arranged in a matrix in XY plane view. The plurality of light-emitting elements 30 are respectively arranged inside the plurality of holes 55.

As illustrated in FIGS. 1 to 3, the light-emitting module 100 is provided with the first light-transmissive member 60 on an upper surface 50T of the light-shielding member 50. The first light-transmissive member 60 is also arranged inside the hole 55 and is arranged on the light-emitting element 30. The first light-transmissive member 60 on the light-emitting element 30 covers a light extraction surface 30S, which is the upper surface of the light-emitting element 30.

In XY plane view, an inner peripheral surface 55W of the hole 55 is arranged outside the outer periphery of the light-emitting element 30. The gap 40 is arranged between the light-emitting element 30 and the inner peripheral surface 55W. Light emitted upward from the light-emitting element 30 is emitted from the light-emitting module 100 via the first light-transmissive member 60. Most of the light emitted to the side of the light-emitting element 30 is reflected by the gap 40 to the side of the light-emitting element 30, and at least a part of the reflected light is emitted upward from the light-emitting element 30. The light transmitted through the gap 40 is shielded by the inner peripheral surface 55W.

The light-emitting element 30 is arranged on the wiring layer 20. The plurality of light-emitting elements 30 are electrically connected to one another by the wiring layer 20. In FIG. 2, the wirings forming the wiring layer 20 are arranged along the row direction of the plurality of light-emitting elements 30 arranged in a matrix. The arrangement of the wirings forming the wiring layer 20 is determined by the circuit configuration of the light-emitting module 100, and is arranged along any direction. Also in this example, the wiring layer 20 includes wirings arranged along the column direction. The light-emitting module 100 can include another wiring layer insulated from the wiring layer 20 depending on the circuit configuration of the light-emitting module 100.

The gap 40 is arranged between the inner peripheral surface 55W of the hole 55 and a lateral surface 30L of the light-emitting element 30. The gap 40 is preferably arranged over the entire outer periphery of the lateral surface 30L of the light-emitting element 30 in XY plane view. The gap 40 is a layer of air and has a refractive index lower than the refractive index of the light-emitting element 30 in contact with the gap 40. Thus, the gap 40 is totally reflective for smaller angles of incidence on the gap 40. That is, since the critical angle between the light-emitting element 30 and the gap 40 is small, the gap 40 can reflect light incident at equal to or greater than the critical angle.

The wiring layer 20 formed of a metal material such as copper (Cu) is arranged near the lateral surface 30L of the light-emitting element 30 and an electrode formation surface 30R below. When such the wiring layer 20 is irradiated with light, the light is absorbed by the metal material forming the wiring layer 20. Thus, when the wiring layer 20 is irradiated with the light emitted from the light-emitting element 30, the light extraction efficiency of the light-emitting element 30 decreases.

In the light-emitting module 100 according to the present embodiment, for example, light emitted from the lateral surface 30L of the light-emitting element 30 is reflected by the gap 40. At least a part of the light reflected by the gap 40 becomes light directed upward inside the light-emitting element 30, for example. Thus, the light emitted from the light-emitting element 30 and irradiated to the wiring layer 20 can be reduced, and the light extraction efficiency of the light-emitting element 30 is improved. Consequently, the light extraction efficiency of the light-emitting module 100 can be improved.

In a case in which the gap 40 surrounds the entire outer periphery of the light-emitting element 30 in XY plane view, the light toward the side of the light-emitting element 30 is reflected by the gap 40 and returned to the light-emitting element 30, and at least a part thereof becomes light directed upward, thereby improving the light extraction efficiency of the light-emitting element 30.

As illustrated in FIG. 3, a plurality of recessed portions 12b are arranged on the first surface 12a. The support member 12 supports the plurality of light-emitting elements 30 respectively arranged in the plurality of recessed portions 12b.

The support member 12 is preferably formed of a light-reflective resin. The light-reflective resin is, for example, a thermosetting resin having excellent heat resistance and light resistance. For example, a silicone resin, an epoxy resin, or the like can be suitably used for the light-reflective resin. For example, a member having light reflectivity can be obtained by mixing a light-reflective filler into a silicone resin. The light-reflective filler can be, for example, TiO₂. The thickness of the support member 12 can be, for example, about 15 μm to 300 μm.

The substrate 10 can include a reinforcing substrate 14. The reinforcing substrate 14 is arranged on a surface side located on the opposite side of the support member 12 from the first surface 12a. The reinforcing substrate 14 is used to reinforce the mechanical strength of the support member 12. In order to reduce the thickness of the light-emitting module 100, the support member 12 is formed sufficiently thin. If the support member 12 is thin, the support member 12 may be prone to warping or wrinkling. In such cases, it can be difficult to maintain the dimensional accuracy of the light-emitting module 100. Arranging the reinforcing substrate 14 suppresses warping and wrinkling of the support member 12 and reinforces the mechanical strength of the support member 12. For example, a substrate using a polyimide-impregnated glass cloth can be used for the reinforcing substrate 14. The thickness of the reinforcing substrate 14 can be, for example, about 25 μm to 200 μm.

A buffer member 1101 is arranged below the reinforcing substrate 14. The buffer member 1101 is provided to alleviate thermal stress or mechanical stress applied to the light-emitting module 100 in the manufacturing step or the like. The buffer member 1101 may be removed after being used in the manufacturing step.

The wiring layer 20 is arranged on the first surface 12a. The plurality of wirings forming the wiring layer 20 are arranged along the X axis direction. These wirings are also arranged on the plurality of recessed portions 12b.

The light-emitting element 30 has the light extraction surface 30S and the electrode formation surface 30R. The electrode formation surface 30R is located on the opposite side from the light extraction surface 30S. A pair of electrodes 32a and 32b are arranged on the electrode formation surface 30R. The light-emitting element 30 has the lateral surface 30L. The lateral surface 30L is located between the light extraction surface 30S and the electrode formation surface 30R. The light extraction surface 30S is an upper surface of the light-emitting element 30, and the electrode formation surface 30R is a lower surface of the light-emitting element 30. The wirings forming the wiring layer 20 are connected to the electrodes 32a and 32b of the light-emitting element 30 in the recessed portions 12b.

In this example, the light-emitting element 30 has a rectangular shape in XY plane view. The shape of the light-emitting element 30 in XY plane view is not limited to a rectangle, and can be a polygon having three or more corners, a circle, or an ellipse. In the case of a polygon, the corners can be chamfered or rounded. In this example, the light-emitting element 30 is a truncated pyramid whose diameter increases from the electrode formation surface 30R toward the light extraction surface 30S. The shape of the light-emitting element 30 is not limited to the above and can be a truncated pyramid, a truncated cone, or an elliptical truncated cone whose diameter decreases from the electrode formation surface 30R toward the light extraction surface 30S. The light-emitting element 30 can have a columnar body having the same diameter from the electrode formation surface 30R to the light extraction surface 30S.

A light-reflecting film 34 is preferably arranged on the lateral surface 30L of the light-emitting element 30. The light-reflecting film 34 is, for example, a distributed Bragg reflector (DBR) film. Including the light-reflecting film 34 on the lateral surface 30L suppresses emission of light from the lateral surface 30L and improves the light extraction efficiency of the light-emitting element 30.

In the light-emitting element 30, light is emitted mainly from the light extraction surface 30S. In this example, the light extraction surface 30S is roughened, and the light emitted from the light extraction surface 30S is diffused over a wide range. The light extraction surface 30S is not limited to this and can be a flat surface substantially flattened. A part of light is also emitted from the lateral surface 30L and the electrode formation surface 30R.

The light-emitting element 30 includes a semiconductor structure, and the pair of electrodes 32a and 32b are connected to a p-type semiconductor layer and an n-type semiconductor layer that form the semiconductor structure. In the semiconductor structure, for example, a structure of a light-emitting diode is achieved by stacking the p-type semiconductor layer, a light-emitting layer, and the n-type semiconductor layer.

The light-emitting layer can have structure with a single active layer, such as a double heterostructure or a single quantum well structure (SQW), or can have structure with a group of active layers, such as a multiple quantum well structure (MQW). The light-emitting layer can emit visible light or ultraviolet light. For example, the visible light can be at least light from blue to red. The semiconductor structure including such light-emitting layer can include, for example, InₓAl_{y}Ga_{1-x-y}N (0≤x, 0≤y,x+y≤1).

The light-emitting element 30 can include two or more light-emitting layers in the semiconductor structure. For example, the semiconductor structure can be a structure including two or more light-emitting layers between the n-type semiconductor layer and the p-type semiconductor layer, or can be a structure in which the n-type semiconductor layer, the light-emitting layer, and the p-type semiconductor layer are sequentially stacked, the staked structure is repeated twice or more. The two or more light-emitting layers can include, for example, light-emitting layers having different emission colors, or can include light-emitting layers having the same emission color. Note that the same emission color can be within the range of emission colors regarded as the same emission color in use, and for example, the principal wavelength of each emission color can vary by a few nm. A combination of emission colors can be appropriately selected, and examples of the combination in a case of including two light-emitting layers include blue light and blue light, green light and green light, red light and red light, ultraviolet light and ultraviolet light, blue light and green light, blue light and red light, or green light and red light.

The light-shielding member 50 is arranged on the first surface 12a. More specifically, the light-shielding member 50 is arranged on the first surface 12a and the wiring layer 20.

The light-shielding member 50 is arranged between the adjacent light-emitting elements 30. The wiring layer 20 is arranged around the light-emitting element 30, and the light-shielding member 50 is arranged so as to cover the wiring layer 20 so that the wiring layer 20 formed of a metal material is not irradiated with light. In a case in which the light-emitting module 100 is used as an image display device, the light-shielding member 50 is provided also for controlling interference of light emitted from each of the adjacent light-emitting elements 30. Thus, the thickness of the light-shielding member 50 is set so as to increase the light extraction efficiency. For example, the thickness of the light-shielding member 50 is larger than the thickness of the light-emitting element 30. The thickness of the light-shielding member 50 is a length along the Z axis direction from the first surface 12a to the upper surface 50T of the light-shielding member 50. That is, the position in the Z axis direction of the upper surface 50T is higher than the maximum position in the Z axis direction of the light extraction surface 30S.

The light emitted from the light-emitting element 30 can be synthesized with the light emitted from another light-emitting element 30 arranged across the light-shielding member 50. The thickness and material of the light-shielding member 50 are set so that the light-emitting module has a planar light source with less luminance unevenness with respect to the light synthesized by the plurality of light-emitting elements 30.

The light-shielding member 50 is formed of a material having a light-shielding property against light emitted from the light-emitting element 30. The light-shielding member 50 can be formed of, for example, a material having light reflectivity. Alternatively, a material that absorbs light can be used for the light-shielding member 50. Preferably, the light-shielding member 50 is formed of a light-reflective resin. When the light-shielding member 50 has light reflectivity, light emitted from the light-emitting element 30 is reflected by the inner peripheral surface 55W and emitted to the outside, thereby improving light extraction efficiency. The light-reflective resin is preferably a thermosetting resin having excellent heat resistance and light resistance. For example, a silicone resin, an epoxy resin, or the like can be suitably used.

The material forming the light-shielding member 50 is not limited to a material having light reflectivity and can be a material that absorbs light. A black resin can be used for a material that absorbs light. Even a resin colored in black can exhibit light-shielding performance.

The thickness of the light-shielding member 50 can be, for example, about 10 μm to 450 μm. In a case in which the light-shielding member 50 is formed of a light-reflective resin, the thickness of the light-shielding member 50 is preferably thick in terms of the light extraction efficiency.

In the above description, each of the plurality of light-emitting elements 30 is arranged for each hole 55 arranged in the light-shielding member 50, but not limited to this. For example, the plurality of light-emitting elements 30 can be arranged inside one hole 55 as one set of light sources. The number of the light-emitting elements 30 arranged inside one hole 55 can be the same throughout the light-emitting module, or can be different depending on the position on the XY plane of the light-emitting module 100, for example.

The first light-transmissive member 60 is arranged on the upper surface 50T of the light-shielding member 50. The first light-transmissive member 60 has a convex body 62. The convex body 62 is arranged on the light-emitting element 30 inside the hole 55. The lower end of the convex body 62 is in contact with the light extraction surface 30S inside the hole 55. Preferably, a part of the convex body 62 in contact with the light extraction surface 30S covers the entire surface of the light extraction surface 30S.

The convex body 62 has an outer peripheral surface 62W of any shaped frustum having a diameter increasing in the positive direction of the Z axis. In this example, the shape of the outer peripheral surface 62W of the convex body 62 is a square in the XY cross section. That is, the lateral surface of the outer peripheral surface 62W of the convex body 62 in this example is trapezoidal. The shape of the outer peripheral surface 62W in XY plane view may be a circle, an ellipse, or a polygon such as a rectangle. In any shape of the outer peripheral surface 62W in XY plane view, the corners of a polygon can be rounded, or the sides of a polygon, the circumference of a circle, and the circumference of an ellipse can be partially irregularly recessed or bulged. In any shape of the outer peripheral surface of each of the plurality of convex bodies has a shape selected from the group consisting of a prism, a cylinder, an ellipsoid, a sphere, a truncated pyramid, a truncated cone, and an elliptical truncated cone, the truncated pyramid, the truncated cone, and the elliptical truncated cone having a diameter decreasing toward the light extraction surface.

The gap 40 is arranged between the light-emitting element 30 and the inner peripheral surface 55W. More specifically, the gap 40 is arranged between the lateral surface 30L of the light-emitting element 30 and the inner peripheral surface 55W at a position opposing the lateral surface 30L. The gap 40 is arranged in contact with the wiring layer 20 between the lateral surface 30L and the inner peripheral surface 55W. The gap 40 is arranged between the lateral surface 30L and the inner peripheral surface 55W, to cover at least the wiring layer 20. Preferably, the gap 40 is arranged over the entire outer periphery of the lateral surface 30L in XY plane view. In this example, the gap 40 is arranged also between the inner peripheral surface 55W and the outer peripheral surface 62W of the convex body 62. The gap 40 is arranged for each light-emitting element 30, and thus, the light-emitting module 100 includes a plurality of gaps 40.

The gap 40 is, for example, a layer of air. The material forming the gap 40 at least has a refractive index lower than the refractive index of the material of a member other than the gap 40 among the members forming the light-emitting module 100. More specifically, the material forming the gap 40 has a refractive index lower than any of the refractive index of the material forming the light-emitting element 30, the refractive index of the material forming the support member 12, and the refractive index of the material forming the first light-transmissive member 60. The material forming the gap 40 can include another gas having a refractive index close to the refractive index of vacuum, such as helium (He) or carbon dioxide (CO₂), for example. The material is not limited to these gases, and in a case in which light is emitted from the light-emitting element 30, the material can be a material having a low refractive index with which the light emitted to directions other than upward from the light-emitting element 30 can be totally reflected on the side of the light-emitting element 30.

In the light-emitting module 100 according to the present embodiment, the gap 40 is arranged also between the inner peripheral surface 55W and the outer peripheral surface 62W. Since the refractive index of the gap 40 is lower than the refractive index of the first light-transmissive member 60 and the refractive index of the convex body 62, among the light emitted through the convex body 62 of the first light-transmissive member 60, a part of the light emitted to the side directions or lower directions is reflected when the angle of incident on the gap 40 is large, and then returns to the inside of the convex body 62. A part of the light transmitted through the convex body 62 reaches the inner peripheral surface 55W of the hole 55. The light reaching the inner peripheral surface 55W is shielded by the light-shielding member 50. In a case in which the light-shielding member 50 is formed of a light-absorbing material, the light reaching the inner peripheral surface 55W is absorbed by the light-shielding member 50. In a case in which the light-shielding member 50 is formed of a light-reflective material, the light reaching the inner peripheral surface 55W is reflected on the gap 40 side, and the reflected light is transmitted through an interface with the gap 40 and is incident on the convex body 62 since the refractive index of the gap 40 is smaller than the refractive index of the convex body 62. At least a part of the light incident on the convex body 62 from the gap 40 is directed upward. The light incident on the gap 40 is incident on the convex body 62 again, and at least a part of the incident light is directed upward. In this way, the light extraction efficiency of the light-emitting element 30 of a light-emitting source of the convex body 62 is improved.

The first light-transmissive member 60 includes a wavelength conversion member 70. The wavelength conversion member 70 is particles of a wavelength conversion substance, for example. The wavelength conversion substance converts light emitted from the light-emitting element 30 into light having a different wavelength. Examples of the wavelength conversion substance include phosphor materials.

The wavelength conversion member 70 can contain one or a plurality of different types of wavelength conversion substances. In the case of containing a plurality of wavelength conversion substances, for example, the wavelength conversion member 70 can contain a β sialon phosphor that emits green light and a fluoride-based phosphor such as a KSF-based phosphor that emits red light. Use of the wavelength conversion member 70 containing the plurality of wavelength conversion substances can expand the color reproduction range of the light-emitting module 100.

As the wavelength conversion substance, a known phosphor can be used. As the phosphor, yttrium-aluminum-garnet-based phosphors (for example, Y₃(Al, Ga)₅O₁₂: Ce), lutetium-aluminum-garnet-based phosphors (for example, Lu₃(Al, Ga)₅O₁₂: Ce), terbium-aluminum-garnet-based phosphors (for example, Tb₃(Al, Ga)₅O₁₂: Ce), CCA-based phosphors (for example, Ca₁₀(PO₄)₆Cl₂: Eu), SAE-based phosphors (for example, Sr₄Al₁₄O₂₅: Eu), chlorosilicate-based phosphors (for example, Ca₈MgSi₄O₁₆Cl₂: Eu), oxynitride-based phosphors, nitride-based phosphors, fluoride-based phosphors, phosphors having a perovskite structure (for example, CsPb (F, Cl, Br, I)₃), quantum dot phosphors (for example, CdSe, InP, AgInS₂, or AgInSe₂), or the like can be used.

Typical examples of the oxynitride-based phosphors include β-sialon-based phosphors (for example, (Si, Al)₃(O, N)₄: Eu) and α-sialon-based phosphors (for example, Ca (Si, Al)₁₂(O, N)₁₆: Eu). Typical examples of the nitride-based phosphors include SLA-based phosphors (for example, SrLiAl₃N₄: Eu), CASN-based phosphors (for example, CaAlSiN₃: Eu), and SCASN-based phosphors (for example, (Sr, Ca) AlSiN₃: Eu). Typical examples of the fluoride-based phosphors include KSF-based phosphors (for example, K₂SiF₆: Mn), KSAF-based phosphors (for example, K₂Si_{0.99}Al_{0.01}F_{5.99}: Mn), and MGF-based phosphors (for example, 3.5MgO·0.5MgF₂·GeO₂: Mn).

The first light-transmissive member 60 is a sheet-like resin member, and for example, an epoxy resin, a silicone resin, or a mixture of these resins can be used, or a light-transmissive material such as glass can be used for the resin material. From the viewpoint of light resistance and moldability, a silicone resin is preferably selected as a base material of the first light-transmissive member 60. As a resin member in which such wavelength conversion substance is dispersed, a phosphor sheet can be used.

An optical member can be arranged on the first light-transmissive member 60. In this case, either or both of a light-diffusion member and a light-scattering member are used for the optical member and arranged in an overlapping manner. The light-diffusion member is, for example, a light-diffusion sheet. The light-scattering member is, for example, a prism sheet. Use of such optical member can further reduce brightness unevenness of the light-emitting module 100.

### Modified Example

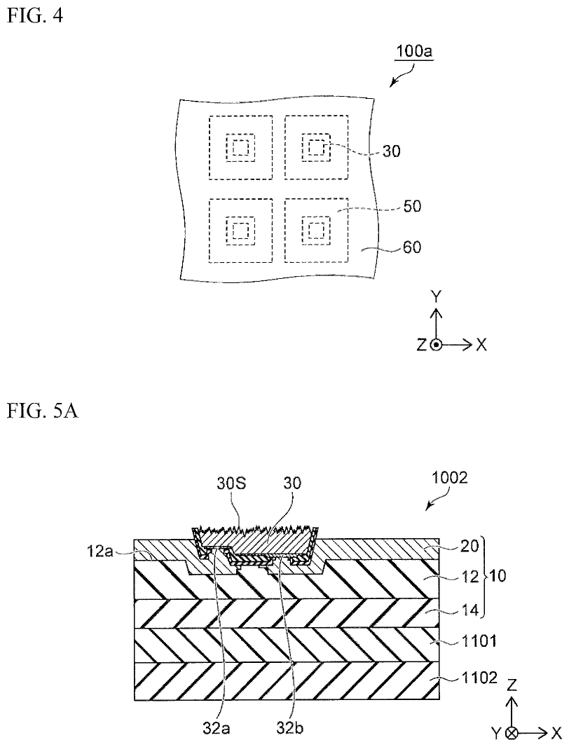

FIG. 4 is a schematic top view illustrating a light-emitting module according to a modified example of the first embodiment.

In the first embodiment, the light-emitting module 100 includes the single light-shielding member 50. The number of light-shielding members 50 is not limited to one, and a plurality of light-shielding members can be provided. In the present modified example, the light-shielding member 50 is arranged for each light-emitting element 30.

As illustrated in FIG. 4, a light-emitting module 100a includes the plurality of light-emitting elements 30 and the plurality of light-shielding members 50. The light-shielding member 50 is arranged for each light-emitting element 30. The light-emitting element 30 is arranged inside the hole 55 formed in the light-shielding member 50 as in the first embodiment. Therefore, in the present modified example, components other than the light-shielding member 50 are the same as those in the first embodiment, and detailed description thereof will be omitted as appropriate.

The first light-transmissive member 60 is arranged on the light-shielding member 50. The first light-transmissive member 60 is arranged also between the adjacent light-shielding members 50. The light-shielding member 50 can be arranged for each of any appropriate plurality of light-emitting elements 30. The plurality of light-emitting elements 30 can be arranged in one hole 55, as in the case of the first embodiment.

Operation of Light-Emitting Module 100

The light-emitting module 100 according to the present embodiment includes the light-shielding member 50 having a plurality of holes 55 arranged in a planar shape. The plurality of light-emitting elements 30 are respectively arranged inside the plurality of holes 55. For this reason, light distribution is controlled for each light-emitting element 30 by the hole 55 of the light-shielding member 50, and the light-emitting module 100 can function as a planar light source with less brightness unevenness. The light-emitting element 30 emits light not only upward but also sideward and downward. The sideward light is converted into light directed upward from the light-emitting element 30 by the gap 40. The downward light can be converted into upward light by using the support member 12, as a light-reflective member, on which the light-emitting element 30 is arranged.

The light emitted upward from the light-emitting element 30 is incident on the convex body 62 of the first light-transmissive member 60. The light incident on the convex body 62 is converted into light having a desired wavelength by the wavelength conversion member 70.

The light emitted upward from the convex body 62 is emitted from the light-emitting module 100 as light of a desired wavelength. The light emitted sideward or downward from the convex body 62 reaches the inner peripheral surface 55W of the hole 55. The light reaching the inner peripheral surface 55W is absorbed or reflected according to the properties of the light-shielding member 50. A part of the light reflected by the light reflectivity of the light-shielding member 50 is returned to the convex body 62 and becomes light directed upward. Thus, the light-emitting module 100 has improved light extraction efficiency for each light-emitting element 30, and light is emitted in a range controlled in a shape in XY plane view of the inner peripheral surface 55W provided for each light-emitting element 30.

Method for Manufacturing Light-Emitting Module 100

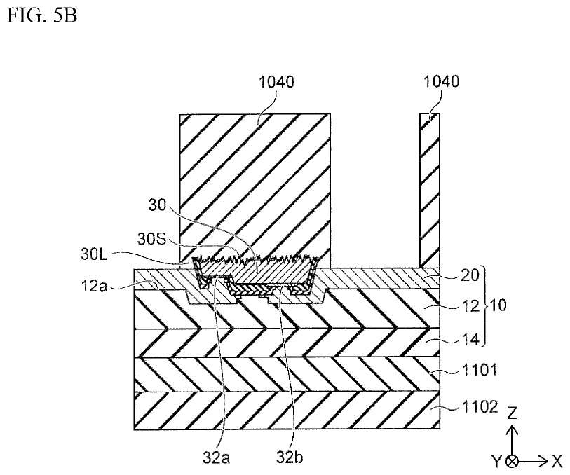

FIGS. 5A to 8B are schematic cross-sectional views illustrating the method for manufacturing the light-emitting module according to the first embodiment.

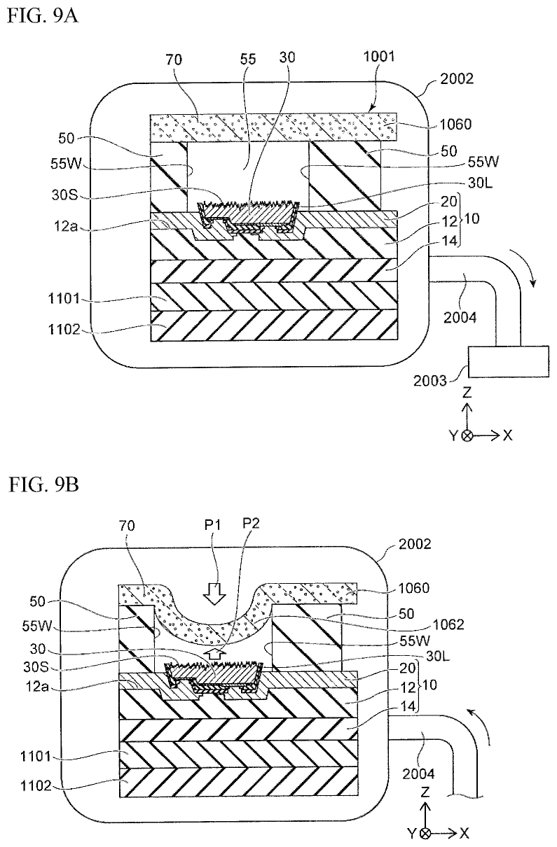

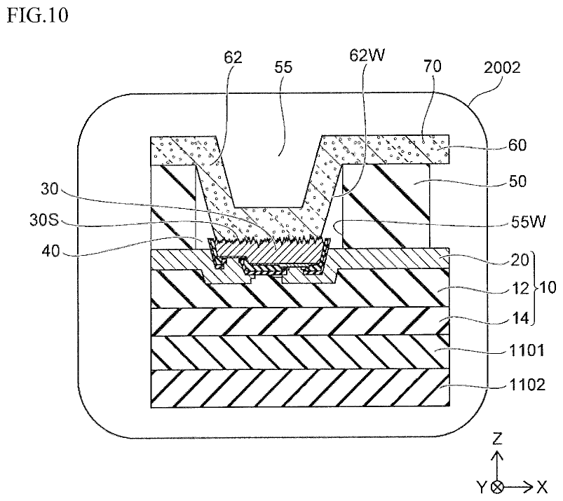

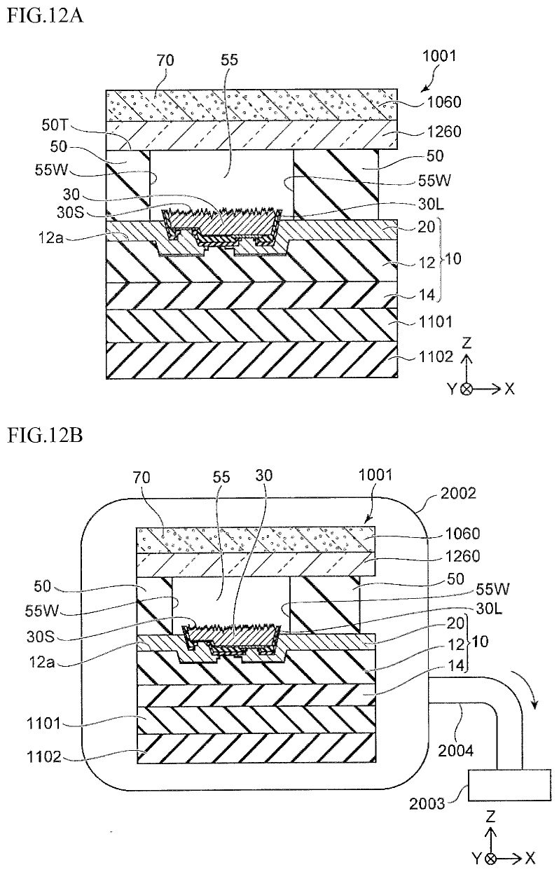

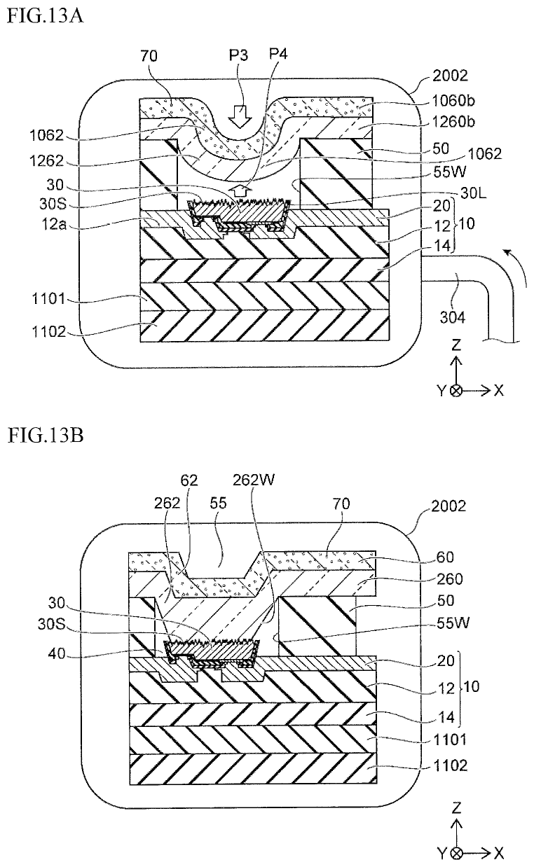

FIGS. 5A to 8B illustrate schematic cross-sectional views of a part corresponding to the cross section taken along line illustrated in FIG. 2. The same applies to FIGS. 9A to 10 illustrating a modified example of the manufacturing method described later, and the same applies to FIGS. 12A to 13B illustrating the method for manufacturing the light-emitting module according to the second embodiment.

As illustrated in FIG. 5A, an intermediate member (second intermediate member) 1002 is prepared. The intermediate member 1002 includes the substrate 10 and the light-emitting element 30. The substrate 10 includes the support member 12 having the first surface 12a, and the light-emitting element 30 is arranged on the first surface 12a. The light-emitting element 30 is connected to the wiring layer 20 via the electrodes 32a and 32b on the first surface 12a. In the intermediate member 1002, the wiring layer 20 is formed by depositing a metal material containing Cu using a manufacturing technique such as sputtering. The wiring layer 20 can be formed by printing fine particles of the metal material containing Cu using an inkjet method, instead of sputtering. A conductive bonding agent such as solder, Au balls, an anisotropic conductive film (ACF), or an anisotropic conductive paste (ACP) can be provided between the light-emitting element 30 and the wiring layer 20. When a conductive bonding agent is used, the wiring layer 20 does not need to contain Cu, and a material other than Cu can also be used.

In the intermediate member 1002, a support substrate 1102 is arranged via the buffer member 1101 to protect each member forming the light-emitting module 100 from thermal stress and mechanical stress during conveyance of the intermediate member 1002 or in the subsequent step. An appropriate material is selected for the support substrate 1102 depending on various types of stress during the step. The buffer member 1101 is arranged between the intermediate member 1002 and the support substrate 1102. The buffer member 1101 can be, for example, a layer containing an adhesive for fixing the intermediate member 1002 to the support substrate 1102 or can be a plurality of layers for absorbing stress due to a difference in expansion coefficient or the like between the substrate 10 and the support substrate 1102.

As illustrated in FIG. 5B, a covering member 1040 is arranged in the intermediate member 1002. The covering member 1040 is arranged for each light-emitting element 30. The covering member 1040 arranged for each light-emitting element 30 is arranged so as to cover the light extraction surface 30S, the lateral surface 30L, the first surface 12a, and the wiring layer 20. For example, a resist is used for the covering member 1040. An acrylic resin or the like is used for a material of the resist. In the step of arranging the covering member 1040, an uncured resist material is applied so as to bury the light-emitting element 30, and the uncured resist material is cured to form the covering member 1040.

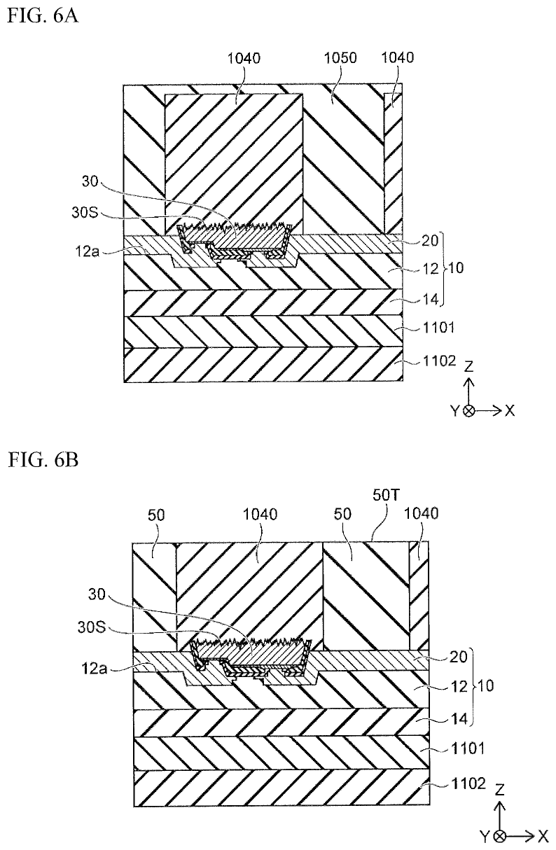

As illustrated in FIG. 6A, a light-shielding member 1050 is arranged so as to fill a space between the covering members 1040. The light-shielding member 1050 is arranged also on the covering member 1040. The light-shielding member 1050 is arranged so as to cover the entire intermediate member 1002. In the step of arranging the light-shielding member 1050, for example, for arranging the light-shielding member 1050, a thermosetting resin is arranged over the entire intermediate member 1002 and cured by heating to form the light-shielding member 1050.

As illustrated in FIG. 6B, the light-shielding member 1050 is cut from the upper surface side until the covering member 1040 is exposed from the light-shielding member 1050. By the cutting of the light-shielding member 1050, the upper surface 50T of the light-shielding member 50 after cutting is flattened. In the forming step of the light-shielding member 1050 described with reference to FIG. 6A, it is possible not to arrange the light-shielding member 1050 on the covering member 1040. In that case, the step of cutting the light-shielding member 1050 can be omitted.

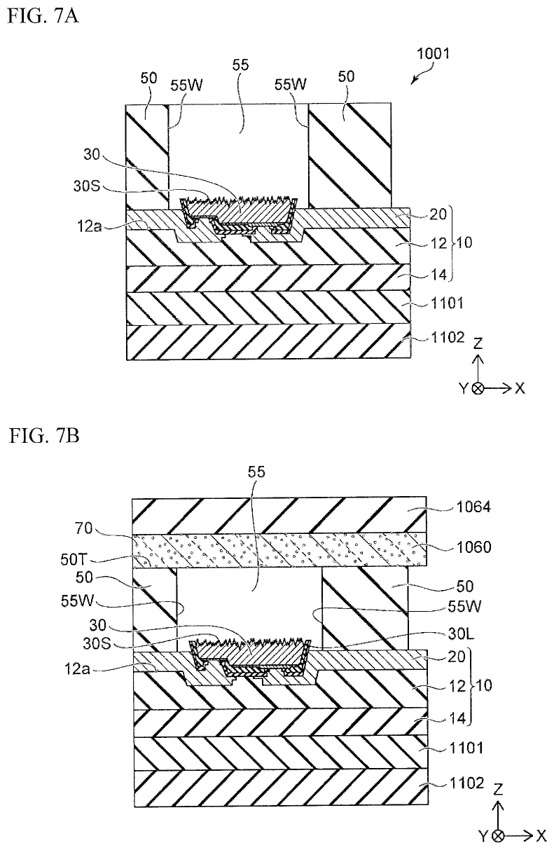

As illustrated in FIG. 7A, the covering member 1040 is removed, and an intermediate member (first intermediate member) 1001 is formed. The intermediate member 1001 is a member in which the light-shielding member 50 having the hole 55 is arranged on the first surface 12a. That is, the intermediate member 1001 includes the substrate 10, the wiring layer 20, the light-emitting element 30, and the light-shielding member 50.

For example, dry etching is used to remove the covering member 1040. By removing the covering member by dry etching, the inner peripheral surface 55W of the hole 55 can be made substantially perpendicular to the first surface 12a, and the gap 40 can be easily formed. The hole 55 is formed at the location from which the covering member 1040 is removed. The light-emitting element 30, the first surface 12a, and the wiring layer 20 are exposed inside the hole 55.

In the manufacturing of the light-emitting module 100, the intermediate member 1002 can be manufactured in, for example, another plant, and the subsequent steps can be executed as described above, or the steps up to the manufacturing of the intermediate member 1001 can be performed at, for example, another plant, and the subsequent steps can be executed as described below. As for the intermediate members 1001 and 1002, those manufactured in another plant or the like can be purchased, and the purchased intermediate members 1001 and 1002 can be put into respective subsequent steps.

As illustrated in FIG. 7B, a first light-transmissive member 1060 attached to a mold release member 1064 is prepared, and the first light-transmissive member 1060 and the mold release member 1064 are arranged on the upper surface 50T of the light-shielding member 50. The mold release member 1064 is a sheet-like resin member that functions as a support member that supports the first light-transmissive member 1060. For example, the first light-transmissive member 1060 is a phosphor sheet containing the wavelength conversion member 70.

The first light-transmissive member 1060 is a thermosetting resin material. The first light-transmissive member 1060 is not cured in an ordinary-temperature state of being attached to the mold release member 1064, and can be deformed by an external force. The first light-transmissive member 1060 is softened by heating at a temperature lower than a predetermined curing temperature, and is cured by heating at a predetermined curing temperature for a predetermined length of time. The softened state facilitates deformation by an external force. The mold release member 1064 is provided with an adhesive layer on the surface on which the first light-transmissive member 1060 is arranged, and the first light-transmissive member 1060 is attached.

The first light-transmissive member 1060 and the mold release member 1064 are arranged such that the side of the first light-transmissive member 1060 is in contact with the upper surface 50T. For example, an adhesive or the like is applied to the upper surface 50T in advance, and the first light-transmissive member 1060 and the mold release member 1064 are arranged on the upper surface 50T so as to close the hole 55.

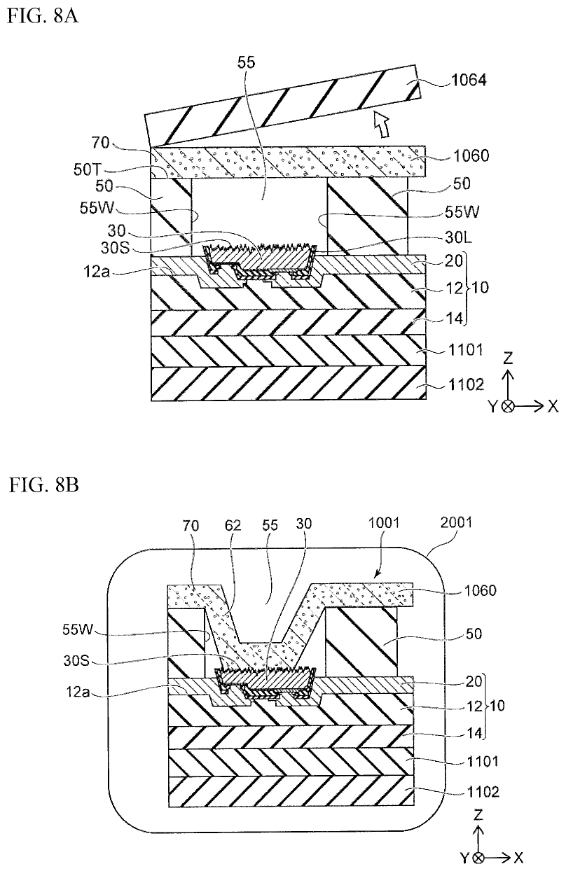

As illustrated in FIG. 8A, the mold release member 1064 is removed. The adhesive force between the mold release member 1064 and the first light-transmissive member 1060 is set to be lower than the adhesive force between the first light-transmissive member 1060 and the upper surface 50T. Therefore, the mold release member 1064 can be easily peeled off from the first light-transmissive member 1060.

As illustrated in FIG. 8B, the intermediate member 1001 is placed inside a chamber 2001 whose internal temperature can be controlled. The temperature inside the chamber 2001 is controlled to reach a set temperature in a set length of time. The temperature inside the chamber 2001 is set to a temperature at which the first light-transmissive member 1060 is softened. The set temperature and the time to reach the temperature are appropriately set depending on the material of the first light-transmissive member 1060. The temperature set for softening the first light-transmissive member 1060 is, for example, about 60° C. to about 100° C. The temperature set for curing the first light-transmissive member 1060 is, for example, about 120° C. to about 180° C.

The first light-transmissive member 1060 softened includes a part arranged substantially in the center of the hole 55 and hanging down on the light-emitting element 30 side due to its own weight. The part arranged substantially in the center of the hole 55 of the first light-transmissive member 1060 hangs down to reach the light-emitting element 30 and covers the light extraction surface 30S. The temperature inside the chamber 2001 is raised to the curing temperature, and in a state where the first light-transmissive member 1060 covers the light extraction surface 30S, the first light-transmissive member 1060 is cured to form the convex body 62. This forms the first light-transmissive member 60 having the convex body 62.

In the step of softening and curing the first light-transmissive member 1060, the temperature inside the chamber 2001 and the length of time are set such that the outer periphery of the hanging part of the first light-transmissive member has a shape of a frustum having a diameter increasing in the positive direction of the Z axis. In the step of softening and curing the first light-transmissive member 1060, the temperature inside the chamber 2001 and the length of time are set such that the gap 40 is formed between the outer peripheral surface 62W of the convex body 62 and the inner peripheral surface 55W of the light-shielding member 50. The temperature and length of time for softening can be set in a plurality of stages between the ordinary temperature and the curing temperature, or the temperature for softening can be continuously changed in a set temperature rise time.

From the viewpoint of controlling the temperature of the entire intermediate member 1001 on which the first light-transmissive member 1060 is arranged, it is preferable to execute the step using the chamber 2001 as described above. More simply, in the step of softening and curing the first light-transmissive member 1060, the intermediate member 1001 can be placed on a temperature controllable stage, and the temperature of the stage can be appropriately set.

FIGS. 9A and 9B are schematic cross-sectional views illustrating a modified example of the method for manufacturing the light-emitting module according to the first embodiment.

The method for forming the convex body 62 of the first light-transmissive member 60 is not limited to the above, and a method described below can be used. In this modified example of the method for manufacturing, the same steps are applied up to the manufacturing step described with reference to FIG. 8A. That is, the steps up to attaching the first light-transmissive member 1060 to the intermediate member 1001 are the same, and the manufacturing step illustrated in FIG. 9A and subsequent drawings and described below is executed subsequent to the steps illustrated in FIG. 8A.

As illustrated in FIG. 9A, the intermediate member 1001 to which the first light-transmissive member 1060 is attached is placed in a chamber 2002. A pump 2003 is fluidly connected to the chamber 2002 via a pipe 2004. The air pressure in the chamber 2002 can be reduced to a desired value by the pump 2003 and the pipe 2004 and return to the atmospheric pressure.

After the intermediate member 1001 to which the first light-transmissive member 1060 is attached is placed in the chamber 2002, the air in the chamber 2002 is exhausted by the pump 2003 and the pipe 2004. The inside of the chamber 2002 is depressurized by the exhaust. That is, the periphery of the intermediate member 1001 to which the first light-transmissive member 1060 is attached is depressurized. The inside of the hole 55 closed by the first light-transmissive member 1060 is also depressurized to the same extent as the inside of the chamber 2002.

As illustrated in FIG. 9B, after the air pressure in the chamber 2002 reaches a predetermined value, air is introduced into the chamber 2002 again to raise an air pressure P1 in the chamber 2002. At this time, since an air pressure P2 inside the hole 55 closed by the first light-transmissive member 1060 is lower than the air pressure P1 inside the chamber 2002, the first light-transmissive member 1060 receives a pressure toward the inside of the hole 55, the pressure being about a difference between the air pressure P1 and the air pressure P2. Therefore, the first light-transmissive member 1060 having a part 1062 deformed into a convex shape toward the hole 55 is formed. In FIG. 9B, the length of the arrows schematically represents the magnitude of the air pressure P1 and P2.

As illustrated in FIG. 10, the first light-transmissive member 60 having the convex body 62 is formed by returning the air pressure of the chamber 2002 to the atmospheric pressure over a predetermined length of time. The convex body 62 is arranged on the light extraction surface 30S inside the hole 55.

In the step of arranging the convex body 62 inside the hole 55, preferably, when the air pressure in the chamber 2002 is returned from the depressurized state to the atmospheric pressure, by controlling the temperature inside the chamber 2002, the convex body 62 can be more reliably formed, and arranged on the light extraction surface 30S.

Specifically, as described with reference to FIGS. 7A to 8B, the material of the first light-transmissive member 1060 can be softened and cured by temperature control, and the temperature inside the chamber 2002 can be controlled. In addition to that, by changing the temperature inside the chamber 2002 stepwise or continuously before returning the air pressure in the chamber 2002 from the depressurized state to the atmospheric pressure, the part 1062 to be drawn to inside the hole 55 can be easily formed. Thus, the convex body 62 having an appropriate shape of the outer peripheral surface 62W is formed. For the temperature control of the first light-transmissive member and the intermediate member 1001, instead of the temperature control inside the chamber 2002, a chamber including a temperature controllable stage is used, and the first light-transmissive member 1060 and the intermediate member 1001 can be placed on the stage.

The forming step of the convex body 62 of the first light-transmissive member 60 is not limited to the above. For example, a member in which the convex body 62 is molded in advance on the surface of the first light-transmissive member 60 can be prepared in accordance with the arrangement of the hole 55 and the light-emitting element.

Then, the support substrate 1102 is removed using laser lift-off or the like. The buffer member 1101 can be removed after removal of the support substrate 1102 or simultaneously with the removal of the support substrate 1102.

Effects of the light-emitting module 100 according to the present embodiment will be described.

In the light-emitting module 100, the gap 40 is arranged between the inner peripheral surface 55W of the hole 55 and the light-emitting element 30. The gap 40 covers at least the wiring layer 20. The gap 40 is, for example, a layer of air. The gap 40 has a refractive index lower than the refractive index of other members forming the light-emitting module 100. Even when the wiring layer 20 is formed of a metal material having a light-absorbing effect, light other than light emitted upward from the light-emitting element 30 is less likely to be incident on the gap 40, which is a layer of air, and is totally reflected inside the light-emitting element 30. Thus, totally reflected light becomes light emitted upward from the light-emitting element 30. Consequently, the light extraction efficiency for each light-emitting element 30 is improved, the brightness of the light-emitting module 100 is improved, and the power consumption is reduced.

The light-emitting element 30 preferably has the light-reflecting film 34 on the lateral surface 30L. Therefore, in the light-emitting element 30, since the emission of light from the lateral surface 30L is suppressed, the light extraction efficiency for each light-emitting element 30 is further improved.

There is a known technique of improving light extraction efficiency of a light-emitting element by including a pillar that is arranged on the light-emitting element and guides light emitted from the light-emitting element, and a lens portion, having a refractive index different from that of the pillar, on a lateral surface of the pillar (see Patent Document 1). This technique has difficulties in reducing the refractive index of the lens portion to a value close to the refractive index of vacuum, and has limitations in improving the light extraction efficiency. On the other hand, in the light-emitting module 100 according to the present embodiment, since the refractive index of the gap 40 is sufficiently close to the refractive index of vacuum, most light emitted from the light-emitting element 30 can be converted into upward light.

In the light-emitting module 100 according to the present embodiment, the gap 40 can be formed between the inner peripheral surface 55W of the hole 55 and the light-emitting element 30 by forming the convex body 62. As described with reference to FIGS. 7A to 8B, the convex body 62 can be easily formed by using the property of softening by heat of the base material forming the first light-transmissive member 60 and the thermosetting property. By appropriately selecting the material of the base material, the plastic property of the base material forming the first light-transmissive member 60 can be used to apply pressure due to a change in air pressure as described with reference to FIGS. 9A to 10. Since these steps do not require a highly dedicated facility or the like, the light-emitting module 100 according to the present embodiment can be easily manufactured.

### Second Embodiment

Configuration of Light-Emitting Module 200

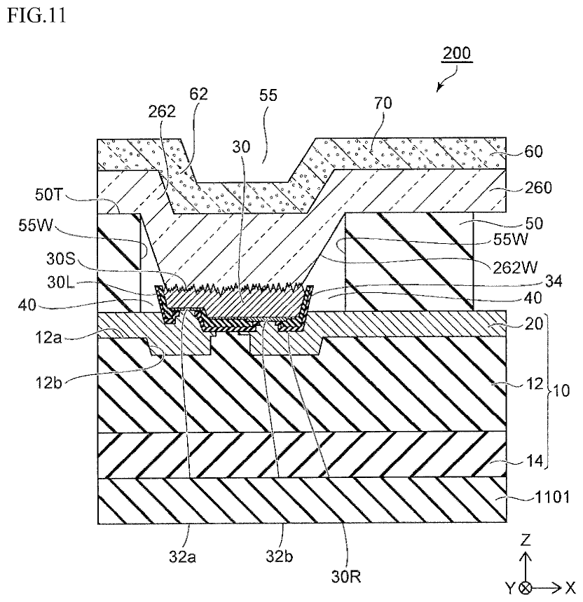

FIG. 11 is a schematic cross-sectional view illustrating the light-emitting module according to the second embodiment.

As illustrated in FIG. 11, a light-emitting module 200 according to the present embodiment includes the substrate 10, the plurality of light-emitting elements 30, the plurality of gaps 40, the light-shielding member 50, the first light-transmissive member 60, and a second light-transmissive member 260.

The present embodiment is different from the first embodiment in that the light-emitting module 200 includes the second light-transmissive member 260 between the first light-transmissive member 60 and the light-emitting element 30, and convex bodies 62 and 262 are formed of the first light-transmissive member 60 and the second light-transmissive member 260, respectively. The configuration of the light-emitting module 200 according to the present embodiment is the same as the configuration of the light-emitting module 100 according to the first embodiment in other points, and the same components are denoted by the same reference characters and detailed description thereof will be omitted as appropriate.

The second light-transmissive member 260 is arranged between the first light-transmissive member 60 and the light-emitting element 30. More specifically, the second light-transmissive member 260 is arranged between the first light-transmissive member 60 and the light extraction surface 30S. The second light-transmissive member 260 is arranged also between the first light-transmissive member 60 and the gap 40. The second light-transmissive member 260 is arranged also between the first light-transmissive member 60 and the upper surface 50T of the light-shielding member 50.

The first light-transmissive member 60 has the convex body 62. The second light-transmissive member 260 has the convex body 262. The two convex bodies 62 and 262 are arranged on the light-emitting element 30 inside the hole 55. The convex body 262 is in contact with the light extraction surface 30S. The convex body 262 has an outer peripheral surface 262W inside the hole 55. The shape of the outer peripheral surface 262W is a frustum having a diameter decreasing toward the light extraction surface 30S in XY plane view. In this example, the shape of the frustum in XY cross-sectional view is a square with rounded corners. The frustum formed by the outer peripheral surface 262W, as in the first embodiment, has any shape such as a circle, an ellipse, or a polygon, and can be partially irregularly recessed or bulged.

The second light-transmissive member 260 has an adhesive layer on the surface on the side having the convex body 262. Thus, the outer peripheral surface 262W of the convex body 262 is an adhesive layer. The second light-transmissive member 260 has an adhesive layer also on the surface on which the first light-transmissive member 60 is arranged. The first light-transmissive member 60 is fixed to the second light-transmissive member 260 via this adhesive layer. That is, the first light-transmissive member 60 is arranged and fixed on the light extraction surface 30S via the second light-transmissive member 260, and is arranged and fixed on the upper surface 50T of the light-shielding member 50 via the second light-transmissive member 260.

The gap 40 is arranged so as to cover the wiring layer 20 between the light-emitting element 30 and the inner peripheral surface 55W of the hole 55. More specifically, the gap 40 is arranged between the lateral surface 30L of the light-emitting element 30 and the inner peripheral surface 55W. The gap 40 is arranged also between the inner peripheral surface 55W and the outer peripheral surface 262W of the convex body 262. Preferably, the gap 40 is arranged over the outer periphery of the lateral surface 30L of the light-emitting element 30 in XY planar view.

Operation of Light-Emitting Module 200

In the light-emitting module 200 according to the present embodiment, the functions and operations of the gap 40 are the same as or similar to those of the first embodiment, and the description thereof will be omitted.

In the light-emitting module 200 according to the present embodiment, the second light-transmissive member 260 is arranged between the first light-transmissive member 60 and the light-emitting element 30. That is, the second light-transmissive member 260 functions as an optical member that optically couples the light-emitting element 30 and the first light-transmissive member 60. Light emitted upward from the light-emitting element 30 is incident on the first light-transmissive member 60 containing the wavelength conversion member 70 via the second light-transmissive member 260. The light emitted from the light-emitting element 30 and incident on the second light-transmissive member 260 is diffused by the second light-transmissive member 260 and converted into light distributed with a wider angle. Thus, brightness unevenness of light is reduced for each light-emitting element 30, and the light-emitting module 200 with less brightness unevenness is achieved.

Method for Manufacturing Light-Emitting Module 200

FIGS. 12A to 13B are schematic cross-sectional views illustrating the method for manufacturing the light-emitting module according to the second embodiment.

In the method for manufacturing the light-emitting module 200 according to the present embodiment, the steps up to the step of preparing the intermediate member 1001 described with reference to FIG. 7A are the same. The steps illustrated in FIG. 12A and subsequent drawings described below are performed following the step illustrated in FIG. 7A.

As illustrated in FIG. 12A, the first light-transmissive member 1060 attached to the second light-transmissive member 1260 is prepared, and the first light-transmissive member 1060 and the second light-transmissive member 1260 are arranged to the intermediate member 1001. The first light-transmissive member 1060 is arranged on the upper surface 50T of the light-shielding member 50 via the second light-transmissive member 1260. The first light-transmissive member 1060 and the second light-transmissive member 1260 are arranged on the intermediate member 1001 so as to close the hole 55.

The intermediate member 1001 including the first light-transmissive member 1060 and the second light-transmissive member 1260 is placed inside the chamber 2002. The chamber 2002 is the same as that described with reference to FIGS. 9A to 10, and is fluidly connected to the pump 2003 via the pipe 2004.

As illustrated in FIG. 12B, air in the chamber 2002 is exhausted by the pipe 2004 and the pump 2003. By exhausting the air inside the chamber 2002, the air pressure inside the hole 55 closed by the first light-transmissive member 1060 and the second light-transmissive member 1260 is reduced along with the air pressure inside the chamber 2002.

As illustrated in FIG. 13A, after the air pressure in the chamber 2002 reaches a predetermined value, the atmospheric air is introduced again into the chamber 2002, whereby an air pressure P3 inside the chamber 2002 becomes higher than an air pressure P4 inside the hole 55 closed by a first light-transmissive member 1060b and a second light-transmissive member 1260b. Thus, the first light-transmissive member 1060b and the second light-transmissive member 1260b are pressed toward the inside of the hole 55 at a pressure based on the difference between the air pressure P3 and the air pressure P4. In FIG. 13A, the lengths of the arrows schematically represent the magnitude of the air pressure P3 and P4.

As illustrated in FIG. 13B, the convex bodies 62 and 262 are formed by appropriately setting the air pressure P3 and P4. When the first light-transmissive member 60 and the second light-transmissive member 260 are formed of a material that is softened and cured depending on the temperature, the convex bodies 62 and 262 can be more reliably formed, as in the case of the first embodiment.

The step of forming the convex bodies 62 and 262 using the pressure controllable chamber 2002 described above can be substituted with a step of forming the convex bodies 62 and 262 using the temperature controllable chamber 2001 described with reference to FIGS. 7A to 8B.

Effects of the light-emitting module 200 according to the present embodiment will be described.

The light-emitting module 200 according to the present embodiment has the effects same as or similar to those of the light-emitting module 100 according to the first embodiment. In addition, the following effects are achieved.

The light-emitting module 200 according to the present embodiment includes the second light-transmissive member 260 between the first light-transmissive member 60 and the light-emitting element 30. As described in the operation of the light-emitting module 200, since the second light-transmissive member 260 optically couples the light-emitting element 30 to the first light-transmissive member 60, the light emitted from the light extraction surface 30S reaches the first light-transmissive member 60 while spreading in the second light-transmissive member 260. Thus, brightness unevenness in the plane in XY plane view is reduced for each light-emitting element 30. Consequently, the light-emitting module 200 with less brightness unevenness can be achieved.

The second light-transmissive member 260 can include a sheet-like base material having both surfaces and adhesive layers on both surfaces of the base material. Thus, the first light-transmissive member 60 can be arranged on one surface and easily fixed. The first light-transmissive member 60 and the second light-transmissive member 260 are arranged on the upper surface 50T of the light-shielding member 50, and the other surface of the second light-transmissive member 260 can be easily fixed to the upper surface 50T. Thus, the step of applying an adhesive for fixing the first light-transmissive member 60 to the upper surface 50T can be omitted, and the period for manufacturing the light-emitting module 200 can be shortened.

In the light-emitting module 200 according to the present embodiment, the convex bodies 62 and 262 can be formed by a general-purpose facility, as in the case of the first embodiment.

### Third Embodiment

Configuration of Light-Emitting Module 300

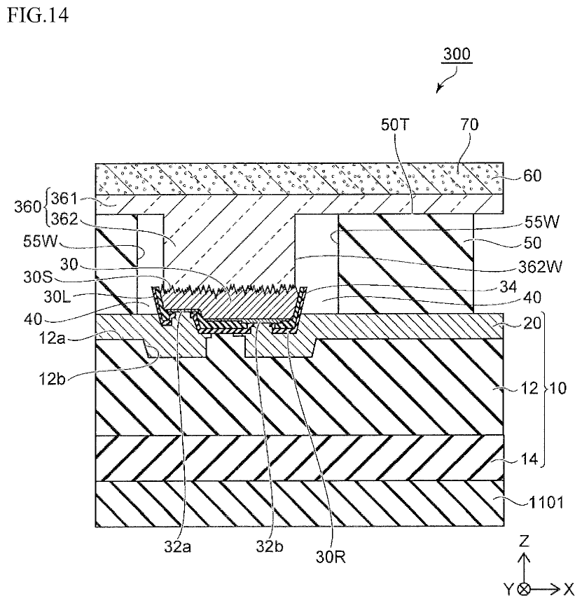

FIG. 14 is a schematic cross-sectional view illustrating the light-emitting module according to the third embodiment.

As illustrated in FIG. 14, a light-emitting module 300 according to the present embodiment includes the substrate 10, the plurality of light-emitting elements 30, the plurality of gaps 40, the light-shielding member 50, the first light-transmissive member 60, and a second light-transmissive member 360.

In the present embodiment, the configuration of the second light-transmissive member 360 is different from that in the other embodiments described above. The other configurations are the same as those in the other embodiments, and the same components are denoted by the same reference characters and detailed description thereof will be omitted as appropriate.

The second light-transmissive member 360 includes a support portion 361 and a plurality of convex bodies 362. The plurality of convex bodies 362 are respectively arranged inside the plurality of holes 55. The support portion 361 is arranged on the plurality of convex bodies 362. The support portion 361 is arranged on the upper surface 50T of light-shielding member 50. The support portion 361 is arranged also on the hole 55.

The second light-transmissive member 360 is formed of, for example, a light-transmissive resin material. The light-transmissive resin material is, for example, a silicone resin, an epoxy resin, or the like. The support portion 361 and the plurality of convex bodies 362 are formed of the same material as that of the second light-transmissive member 360, and are formed integrally, for example.

The convex body 362 is arranged on the light-emitting element 30 inside the hole 55, and the lower end of the convex body 362 is in contact with the light extraction surface 30S. The convex body 362 covers most of the light extraction surface 30S except for the vicinity of the outer periphery of the light extraction surface 30S in XY plane view. The convex body 362 preferably covers the entire surface of the light extraction surface 30S.

An outer peripheral surface 362W of the convex body 362 is substantially a square in XY plane view and has a shape of a lateral surface of a prism. The shape of the outer peripheral surface 362W in XY plane view is substantially the same in the Z axis direction. The shape of the outer peripheral surface 362W in XY plane view is not limited to a square, and can be another polygon including a rectangle, or can be a circle or an ellipse. The shape of the outer peripheral surface 362W in XY plane view can be any other shape as long as the gap 40 is formed between the outer peripheral surface 362W and the inner peripheral surface 55W of the hole 55.

The gap 40 is arranged to cover the wiring layer 20 between the inner peripheral surface 55W of the hole 55 and the lateral surface 30L of the light-emitting element 30. The gap 40 is preferably arranged over the outer periphery of the lateral surface 30L in XY plane view, as in the case of other embodiments described above. The gap 40 is arranged also between the inner peripheral surface 55W and the outer peripheral surface 362W of the convex body 362. The gap 40 has a refractive index lower than the refractive index of other components other than the gap 40. The gap 40 is, for example, a layer of air.

Operation of Light-Emitting Module 300

Since the light-emitting module 300 according to the present embodiment operates in a manner same as or similar to the light-emitting modules 100 and 200 according to the other embodiments described above, the description thereof will be omitted.

Method for Manufacturing Light-Emitting Module 300

In the method for manufacturing the light-emitting module 300 according to the present embodiment, the steps up to the step of preparing the intermediate member 1001 described with reference to FIG. 7A are the same. The step described below is performed following the step illustrated in FIG. 7A.

In the light-emitting module 300 according to the present embodiment, the second light-transmissive member 360 is prepared. The second light-transmissive member 360 having the plurality of convex bodies 362 can be formed in advance using a sealing mold or the like. The prepared second light-transmissive member 360 is arranged on the intermediate member 1001. In the step of arranging the second light-transmissive member 360, by using, for example, an adhesive or the like, the second light-transmissive member 360 is fixed so that the lower end of the convex body 362 is placed on the light extraction surface 30S, and is fixed on the upper surface 50T of the light-shielding member 50.

Since the shape of the outer peripheral surface 362W of the convex body 362 is formed in advance in accordance with the shape of the inner peripheral surface 55W of the hole 55, the gap 40 is reliably arranged between the inner peripheral surface 55W and the outer peripheral surface 362W.

Effects of the light-emitting module 300 according to the present embodiment will be described.

The light-emitting module 300 according to the present embodiment has the effects same as or similar to those of the other embodiments described above. In addition, the light-emitting module 300 according to the present embodiment includes the second light-transmissive member 360 including the convex body 362 having substantially the same diameter in the Z axis direction. Therefore, the gap 40 between the inner peripheral surface 55W of the hole 55 and the outer peripheral surface 362W of the convex body 362 can be stably and reliably formed. This makes it possible to achieve a high yield and contribute to cost reduction of the light-emitting module 300.

### Fourth Embodiment

Configuration of Light-Emitting Module 400

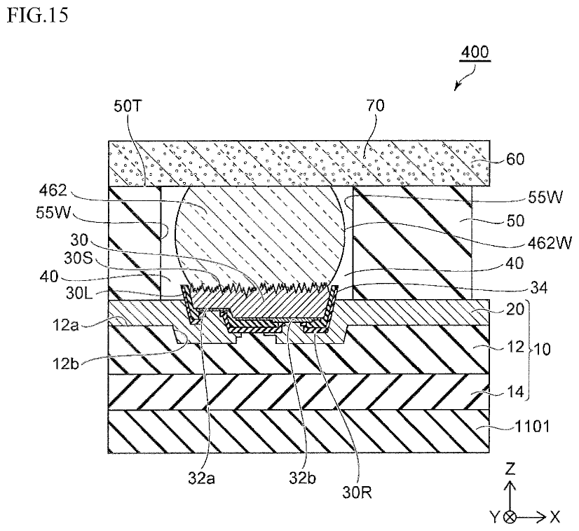

FIG. 15 is a schematic cross-sectional view illustrating the light-emitting module according to the fourth embodiment.

As illustrated in FIG. 15, a light-emitting module 400 according to the present embodiment includes the substrate 10, the plurality of light-emitting elements 30, the plurality of gaps 40, the light-shielding member 50, the first light-transmissive member 60, and a plurality of convex bodies 462.

The light-emitting module 400 according to the present embodiment is different from the other embodiments described above in that the plurality of convex bodies 462 are provided. The light-emitting module 400 according to the present embodiment is the same as that of the above-described other embodiments in other points, and the same components are denoted by the same reference characters and detailed description thereof will be omitted as appropriate.

The plurality of convex bodies 462 are respectively arranged inside the plurality of holes 55. The plurality of convex bodies 462 are arranged on the plurality of light-emitting elements 30. The convex body 462 is arranged in contact with the light extraction surface 30S, and preferably covers most of the light extraction surface 30S.

The shape of an outer peripheral surface 462W of the convex body 462 is a flat spherical surface crushed vertically. Thus, the outer peripheral surface 462W has, in XY plane view, a different diameter from the entrance of the hole 55 toward the light extraction surface 30S. The diameter of the outer peripheral surface 462W in XY plane view gradually increases in the negative direction of the Z axis, and decreases toward the light extraction surface 30S. Since it is sufficient that the gap 40 is formed between the outer peripheral surface 462W and the inner peripheral surface 55W, the outer peripheral surface 462W does not need to be a smooth spherical surface.

The convex body 462 is formed of a light-transmissive material. Therefore, the light emitted from the light extraction surface 30S is transmitted through the convex body 462. The convex body 462 is formed of, for example, a light-transmissive resin material, and the resin material is, for example, a silicone resin.

The first light-transmissive member 60 is arranged on the plurality of convex bodies 462. The first light-transmissive member 60 is arranged so as to close the hole 55, and is arranged also on the upper surface 50T of the light-shielding member 50.

The gap 40 is arranged to cover the wiring layer 20 between the inner peripheral surface 55W of the hole 55 and the outer peripheral surface 462W of the convex body 462. The gap 40 is arranged also between the lateral surface 30L of the light-emitting element 30 and the outer peripheral surface 462W.

### Modified Example

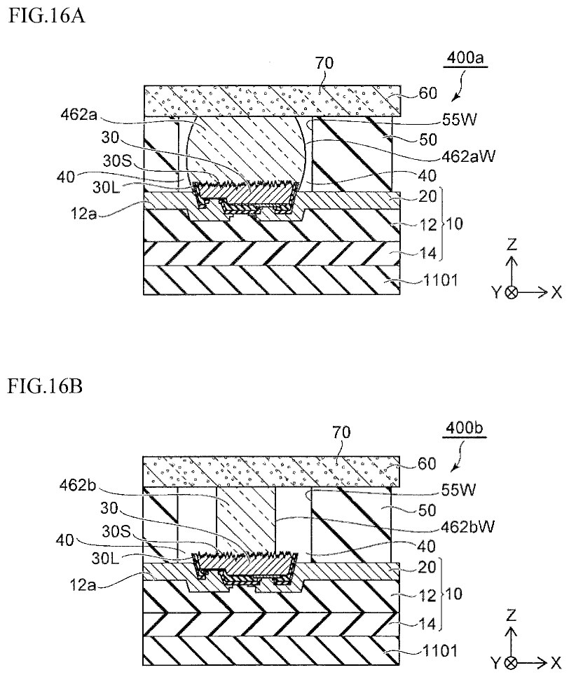

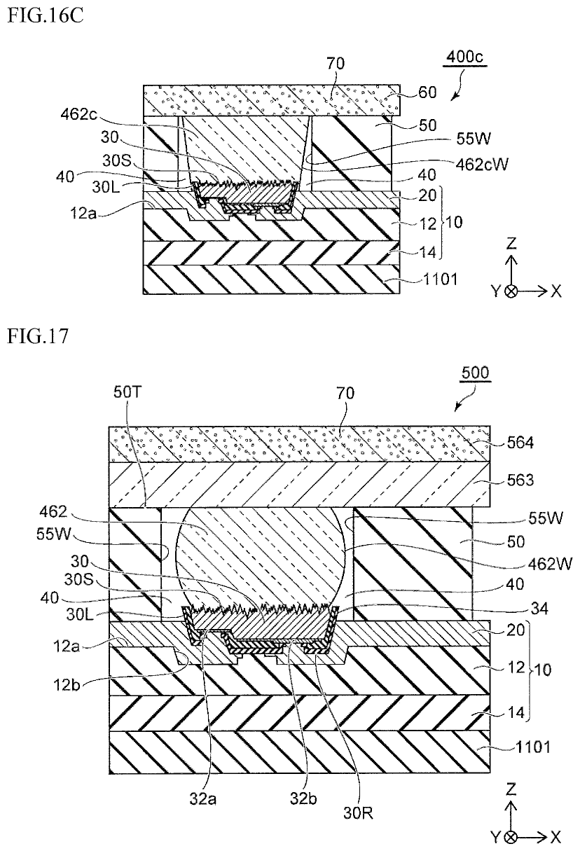

FIGS. 16A to 16C are schematic cross-sectional views illustrating a light-emitting module according to a modified example of the fourth embodiment.

The modified example illustrated in FIGS. 16A to 16C is different from the fourth embodiment in that a convex body having a different shape from the convex body 462 of the light-emitting module 400 of the fourth embodiment is provided. The other points are the same as in the fourth embodiment, and the same components are denoted by the same reference characters and detailed description thereof will be omitted.

As illustrated in FIG. 16A, a light-emitting module 400a includes a convex body 462a. The shape of the convex body 462a of the light-emitting module 400a in the present modified example is a flat sphere with a larger diameter in XY plane view than the convex body 462 of the fourth embodiment. The convex body 462a is arranged between the first light-transmissive member 60 and the light-emitting element 30. The convex body 462a is arranged in contact with the light extraction surface 30S of the light-emitting element 30 and covers the entire surface of the light extraction surface 30S.

The convex body 462a also covers the lateral surface 30L of the light-emitting element 30. Thus, the gap 40 is arranged so as to cover the wiring layer 20 between the inner peripheral surface 55W of the hole 55 and an outer peripheral surface 462aW of the convex body 462a.

The convex body 462a is transmissive, and is formed of the same or similar material as in the fourth embodiment.

In the present modified example, since the convex body 462a covers the light extraction surface 30S and the lateral surface 30L of the light-emitting element 30, light emitted sideward from the light-emitting element 30 and light directed sideward from the vicinity of the outer periphery of the light extraction surface 30S are totally reflected by the gap 40 and converted into light directed upward.

As illustrated in FIG. 16B, a light-emitting module 400b includes a convex body 462b. The convex body 462b of the light-emitting module 400b in the present modified example has a columnar body. The shape of an outer peripheral surface 462bW of the convex body 462b in XY plane view is substantially the same in the Z axis direction. In the present modified example, the convex body 462b covers a part of the vicinity of the center of the light extraction surface 30S in XY plane view. Thus, the length of the gap 40 between the inner peripheral surface 55W of the hole 55 and the outer peripheral surface 462bW is longer than that in the other embodiments and modified examples described above. In this case, light emitted from a part, where the light extraction surface 30S is not covered with the convex body 462b, of the light extraction surface 30S is emitted to the gap 40. Since the gap 40 has a refractive index lower than that of the convex body 462b, a part of the light incident on the gap 40 becomes easily incident on the convex body 462b, and most of the light incident on the convex body 462b is extracted upward.

As illustrated in FIG. 16C, a light-emitting module 400c includes a convex body 462c. The convex body 400c of the light-emitting module 462c of the present modified example has a frustum shape. The diameter of an outer peripheral surface 462cW of the convex body 462c in XY plane view decreases from the entrance of the hole 55 toward the light extraction surface 30S.

In this example, the convex body 462c covers the entire surface of the light extraction surface 30S and also covers the lateral surface 30L. The gap 40 covers the wiring layer 20 between the inner peripheral surface 55W of the hole 55 and the outer peripheral surface 462cW of the convex body 462c. Thus, among the light emitted from the light-emitting element 30, the light emitted sideward is confined by the convex body 462c, is converted into upward light inside the light-emitting element 30 and the like and then is emitted.

Method for Manufacturing Light-Emitting Modules 400 and 400a to 400c

The intermediate member 1001 described with reference to FIG. 7A is prepared. The convex body 462 is directly formed in the hole 55 of the intermediate member 1001 using, for example, a technique of forming fine particles. The technique for forming fine particles is, for example, a printing technique, an inkjet technique, a potting technique, or the like. As a technique for forming fine particles, an appropriate technique is selected depending on the diameter of the hole 55 in XY plane view, the thickness of the light-shielding member 50, the shape of the convex body described above as a modified example, or the like.

In the intermediate member 1001 in which the convex body 462 is formed, the first light-transmissive member 60 is arranged and fixed on the upper surface 50T of the light-shielding member 50 and the convex body 462.

Effects of the light-emitting module 400 according to the present embodiment and the light-emitting modules 400a to 400c of the modified example thereof will be described.

The light-emitting module 400 according to the present embodiment and the light-emitting modules 400a to 400c of the modified example thereof have the effects that are the same as or similar to those of the light-emitting module 100 according to the first embodiment described above. In addition, the light-emitting module 400 according to the present embodiment includes the convex body 462 that has a flat sphere shape. The convex body 462 has transmissivity, and provides a path of light emitted from the light-emitting element 30. Since the light from the light-emitting element 30 is spread at a wide angle by the convex body 462 and is incident on the first light-transmissive member 60, the brightness for each light-emitting element 30 is made more uniform.

Appropriate light distribution can be achieved by arranging the convex body as in each modified example in accordance with the structure of the light-emitting element 30 and the like.

### Fifth Embodiment

Configuration of Light-Emitting Module 500

FIG. 17 is a schematic cross-sectional view illustrating the light-emitting module according to the fifth embodiment.

As illustrated in FIG. 17, a light-emitting module 500 according to the present embodiment includes the substrate 10, the plurality of light-emitting elements 30, the plurality of gaps 40, the light-shielding member 50, a third light-transmissive member 563, a fourth light-transmissive member 564, and the plurality of convex bodies 462. The configuration of the light-emitting module 500 according to the present embodiment is different from the configuration of the light-emitting module 400 according to the fourth embodiment in that the third light-transmissive member 563 is included. The fourth light-transmissive member 564 is the same as the first light-transmissive member 60 of the other embodiments described above. The convex body 462 is the same as the convex body 462 of the fourth embodiment. The other components can also be the same as those in the other embodiments described above, and the same components are denoted by the same reference characters and detailed description thereof will be omitted as appropriate.

As in the fourth embodiment, the convex body 462 is arranged on the light-emitting element 30 inside the hole 55. Each modified example of the fourth embodiment can be applied to the shape of the outer peripheral surface 462W of the convex body 462. The convex body 462 is formed of a light-transmissive material, and functions as a member that optically couples the light-emitting element 30 and the fourth light-transmissive member 564 including the wavelength conversion member 70 together with the third light-transmissive member 563.

The third light-transmissive member 563 is arranged on the upper surface 50T of the light-shielding member 50 and on the convex body 462. More specifically, the third light-transmissive member 563 is arranged between the fourth light-transmissive member 564 and the upper surface 50T so as to close the hole 55. The third light-transmissive member 563 has the material and configuration that are the same as or similar to those of the second light-transmissive member 260 of the second embodiment. That is, the third light-transmissive member 563 has adhesive layers on both sides, and the fourth light-transmissive member 564 is arranged on one side via the adhesive layer. The third light-transmissive member 563 is arranged and fixed on the upper surface 50T of the light-shielding member 50 via the adhesive layer on the other side, and is arranged and fixed on a convex body 562.

The light-emitting module 500 according to the present embodiment operates in the same or similar manner as other embodiments described above.

The light-emitting module 500 according to the present embodiment can be manufactured in the same or similar manner as the other embodiments described above. That is, the intermediate member 1001 illustrated in FIG. 7A is prepared, and the convex body 462 is directly formed inside the hole 55. Thereafter, as described with reference to FIG. 12A, the third light-transmissive member 563 to which the fourth light-transmissive member 564 is attached is arranged on the intermediate member 1001 on which the convex body 462 is formed.

The embodiments described above enable the light-emitting module with improved light extraction efficiency and the method for manufacturing the light-emitting module.

While several embodiments of the present invention have been described above, these embodiments are presented by way of example, and are not intended to limit the scope of the invention. These novel embodiments may be implemented in various other forms, and various omissions, substitutions, and changes may be made without departing from the spirit of the invention. These embodiments and variations thereof are included in the scope and spirit of the invention, and are within the scope of the invention described in the claims and equivalents thereof. Furthermore, the aforementioned embodiments may be implemented in combination with each other.
10 Substrate
12 Support member
14 Reinforcing substrate
20 Wiring layer
30 Light-emitting element
40 Gap
50 Light-shielding member
55 Hole
55W Inner peripheral surface
60 First light-transmissive member
62, 262, 362, 462, 462a to 462c Convex body
62W, 262W, 362W, 462W, 462aW to 462cW Outer peripheral surface
70 Wavelength conversion member
100, 100a, 200, 300, 400, 400a to 400c, 500 Light-emitting module
260, 360 Second light-transmissive member
563 Third light-transmissive member
564 Fourth light-transmissive member
1001, 1002 Intermediate member
1040 Covering member
1050 Light-shielding member
1060 First light-transmissive member

1. Alight-emitting module, comprising:
a substrate comprising a support member having a first surface and a wiring layer arranged on the first surface;
a light-shielding member arranged on the first surface and having a plurality of holes in plan view;
a plurality of light-emitting elements respectively arranged inside the plurality of holes on the first surface and electrically connected to the wiring layer;
a first light-transmissive member having a plurality of convex bodies respectively arranged on light extraction surfaces of the plurality of light-emitting elements inside the plurality of holes; and
a plurality of gaps respectively arranged in contact with the wiring layer between the plurality of light-emitting elements and inner peripheral surfaces of the plurality of holes.

2. The light-emitting module according to claim 1, wherein
in plan view,
the plurality of gaps surround respective outer peripheries of lateral surfaces of the plurality of light-emitting elements, and
the inner peripheral surfaces of the plurality of holes surround respective outer peripheries of lateral surfaces of the plurality of light-emitting elements via the plurality of gaps.

3. The light-emitting module according to claim 1, wherein an outer peripheral surface of each of the plurality of convex bodies has a shape selected from a group consisting of a prism, a cylinder, an ellipsoid, a sphere, a truncated pyramid, a truncated cone, and an elliptical truncated cone, the truncated pyramid, the truncated cone, and the elliptical truncated cone having a diameter decreasing toward the light extraction surface.

4. The light-emitting module according to claim 1, wherein the first light-transmissive member comprises a wavelength conversion member.

5. The light-emitting module according to claim 4, wherein the plurality of convex bodies comprise the wavelength conversion member.

6. The light-emitting module according to claim 1, wherein
the first light-transmissive member further comprises a second light-transmissive member arranged on the plurality of convex bodies, and
the second light-transmissive member comprises a wavelength conversion member.

7. The light-emitting module according to claim 1, wherein
the first light-transmissive member comprises a third light-transmissive member arranged on the convex body and a fourth light-transmissive member arranged on the third light-transmissive member, and
the fourth light-transmissive member comprises a wavelength conversion member.

8. The light-emitting module according to claim 1, wherein each of the plurality of light-emitting elements comprises a light-reflecting film arranged on a lateral surface located between the light extraction surface and an electrode formation surface located on an opposite side of each of the plurality of light-emitting elements from the light extraction surface.

9. The light-emitting module according to claim 4, wherein each of the plurality of light-emitting elements comprises a light-reflecting film arranged on a lateral surface located between the light extraction surface and an electrode formation surface located on an opposite side of each of the plurality of light-emitting elements from the light extraction surface.

10. A light-emitting module, comprising:
a substrate comprising a support member having a first surface and a wiring layer arranged on the first surface;
a light-shielding member arranged on the first surface and having a hole in plan view;
a light-emitting element arranged inside the hole on the first surface and electrically connected to the wiring layer;
a first light-transmissive member having a convex body arranged on a light extraction surface of the light-emitting element inside the hole; and
a gap arranged in contact with the wiring layer between the light-emitting element and an inner peripheral surface of the hole.

11. The light-emitting module according to claim 10, wherein the first light-transmissive member comprises a wavelength conversion member.

12. The light-emitting module according to claim 10, wherein the convex body comprises a wavelength conversion member.

13. A method for manufacturing a light-emitting module, the method comprising:
preparing a first intermediate member comprising a substrate comprising a support member having a first surface and a wiring layer arranged on the first surface, a plurality of light-emitting elements arranged on the first surface apart from one another and connected to the wiring layer, and a light-shielding member comprising a plurality of holes and in which the plurality of light-emitting elements are respectively arranged inside the plurality of holes; and
arranging a plurality of convex bodies having transmissivity on upper surfaces of the plurality of light-emitting elements via the plurality of holes,
wherein the arranging of the plurality of convex bodies on the upper surfaces of the plurality of light-emitting elements includes arranging a plurality of gaps in contact with the wiring layer respectively between the plurality of light-emitting elements and inner peripheral surfaces of the plurality of holes.

14. The method according to claim 13, wherein
the preparing of the first intermediate member comprises
preparing a second intermediate member comprising the substrate and the plurality of light-emitting elements,
arranging, in the second intermediate member, a plurality of covering members configured to cover the upper surfaces of the plurality of light-emitting elements, lateral surfaces of the plurality of light-emitting elements, and the first surfaces around the plurality of light-emitting elements,
arranging a light-shielding member so as to fill a space between the plurality of covering members, and
removing the plurality of covering members and forming the plurality of holes.

15. The method according to claim 13, wherein
the arranging of the plurality of convex bodies on the upper surfaces of the plurality of light-emitting elements comprises
arranging a first light-transmissive member having thermoplasticity on the plurality of holes, and
heating the first light-transmissive member having thermoplasticity on the plurality of holes to form the plurality of convex bodies from the first light-transmissive member and arranging, on the upper surfaces of the plurality of light-emitting elements, the plurality of convex bodies formed.

16. The method according to claim 14, wherein
the arranging of the plurality of convex bodies on the upper surfaces of the plurality of light-emitting elements comprises
arranging a first light-transmissive member having thermoplasticity on the plurality of holes, and
heating the first light-transmissive member having thermoplasticity on the plurality of holes to form the plurality of convex bodies from the first light-transmissive member and arranging, on the upper surfaces of the plurality of light-emitting elements, the plurality of convex bodies formed.

17. The method according to claim 13, wherein
the arranging of the plurality of convex bodies on the upper surfaces of the plurality of light-emitting elements comprises
arranging a first light-transmissive member having plasticity on the plurality of holes, and
after placing the first light-transmissive member having plasticity on the plurality of holes in a depressurized atmosphere, increasing air pressure of the atmosphere, forming the plurality of convex bodies from the first light-transmissive member, and arranging, on the upper surfaces of the plurality of light-emitting elements, the plurality of convex bodies formed.

18. The method according to claim 14, wherein
the arranging of the plurality of convex bodies on the upper surfaces of the plurality of light-emitting elements comprises
arranging a first light-transmissive member having plasticity on the plurality of holes, and
after placing the first light-transmissive member having plasticity on the plurality of holes in a depressurized atmosphere, increasing air pressure of the atmosphere, forming the plurality of convex bodies from the first light-transmissive member, and arranging, on the upper surfaces of the plurality of light-emitting elements, the plurality of convex bodies formed.

19. The method according to claim 13, wherein
the arranging of the plurality of convex bodies on the upper surfaces of the plurality of light-emitting elements comprises directly arranging the plurality of convex bodies on the upper surfaces of the plurality of light-emitting elements via the plurality of holes.

20. The method according to claim 14, wherein
the arranging of the plurality of convex bodies on the upper surfaces of the plurality of light-emitting elements comprises directly arranging the plurality of convex bodies on the upper surfaces of the plurality of light-emitting elements via the plurality of holes.
